(19) United States
(12) Patent Application Publication
(10) Pub. No.: US 2015/0091423 A1
(43) Pub. Date: Apr. 2, 2015

(54) CARRYING DEVICE AND SELF-LOCKING STRUCTURE THEREOF

(71) Applicant: WISTRON CORP., NEW TAIPEI CITY (TW)

(72) Inventors: ZHAO-PING FU, NEW TAIPEI CITY (TW); CHONG-XING ZHU, NEW TAIPEI CITY (TW)

(73) Assignee: WISTRON CORP., NEW TAIPEI CITY (TW)

(21) Appl. No.: 14/219,312

(22) Filed: Mar. 19, 2014

(30) Foreign Application Priority Data
Sep. 30, 2013 (CN) 201310461568.9

(51) Int. Cl. H05K 7/14

(52) U.S. Cl. CPC H05K 7/1489; H05K 7/1488
USPC 312/257.1

(57) ABSTRACT

A carrying device and a self-lock structure thereof are provided, which are adapted for a server to bear a human-computer interface device. The carrying device includes a carrying-component and a receiving cage. The self-lock structure consists of a cantilever fixed on the carrying component and an interference portion formed on the receiving cage. A structural interference is generated between a protruding portion formed on the cantilever and a lock slot formed in the interference portion while the carrying-component being inserted to the receiving cage. The cantilever may generate a corresponding elastic force to serve as power resource for self-locking, thereby the functions of self-locking and overload protection are achieved.

### BACKGROUND OF THE INVENTION

1. Field of the Invention

The present disclosure relates to a carrying device; in particular, to a carrying device a self-locking structure thereof, adapted to carry a human-computer interface device for a server.

2. Description of Related Art

Servers integrate multiple hard drives, processors and human-computer interface devices. Design of housing structures of the servers need to take into account convenience of mounting and dismounting, and safety. Human-computer interface devices are often designed to be modules that are easily dismounted to facilitate maintenance by maintenance personnel.

Electronic devices can be directly mounted in a housing of a server by using screws or by using a dismountable carrying structure. Current servers usually include a housing and a plurality of carrying structures such as a carrying plate having a handle at the front end thereof and sliding wheels thereunder so the carrying plate can be pulled out and pushed in by users. A plurality of accommodating grooves are usually arranged on the carrying plate for mounting hard drives, back panels or other electronic devices. Methods for mounting include locking and screwing. The server has locking elements therein for fixing the carrying plates. The external surface of the housing has a button for controlling the locking elements to release the carrying plate.

Carrying plates are commonly used by servers. However, the locking elements and the linkage structure of the button are often complicated and require high production costs. Current designs do not provide economical solutions.

Hence, the present inventor believes the above mentioned disadvantages can be overcome, and through devoted research combined with application of theory, finally proposes the present disclosure which has a reasonable design and effectively improves upon the above mentioned disadvantages.

### SUMMARY OF THE INVENTION

The present disclosure provides a carrying device having a simple self-locking structure adapted to carry a human-computer interface device and other electronic devices for a server. The self-locking structure is simple protects against overload, preventing damage due to improper usage.

An embodiment of the present disclosure provides a carrying device adapted to carry an electronic device such as a human-computer interface device or a control panel. The carrying device includes a carrying unit and a receiving cage. A cantilever is disposed at one end of the carrying unit. A protruding portion is formed at one side of the cantilever. A release portion is formed at the front end of the cantilever. The receiving cage is disposed in the server and has an insertion slot. The carrying unit can be inserted into the insertion slot from the front end of the insertion slot. An interference portion is formed on a side wall of the receiving cage. The interference portion recedes inward toward the rear of the insertion slot and has a locking slot behind the insertion slot. The interference portion and the cantilever form a self-locking structure. The protruding portion extends into the locking slot to create structural interference. One edge of the locking slot has a guiding portion, a neck portion and a locking portion. The guiding portion guides the movement of the protruding portion, such that the protruding portion moves along the guiding portion into a retaining slot defined by the neck portion and the locking portion.

In an embodiment of the present disclosure, the guiding portion is a slanted edge for interfering with the protruding portion such that an elastic force is created in the cantilever.

In an embodiment of the present disclosure, the interference portion has a blocking portion opposite the locking portion. The edge having a guiding portion, a neck portion and a locking portion can be an upper edge or a lower edge of the locking slot.

In an embodiment of the present disclosure, the abovementioned edge has a protruding rail projecting outward for the protruding portion to slide on.

In an embodiment of the present disclosure, the receiving cage has a frame body and an upper cover disposed on the frame body. The upper cover and the frame body form the insertion slot.

In an embodiment of the present disclosure, the release portion is arranged outside the locking slot.

An embodiment of the present disclosure further provides a self-locking structure of a carrying device. The carrying device has a carrying unit and a receiving cage. The receiving cage is disposed in the server. The carrying unit is for carrying an electronic device. The receiving cage has an insertion slot. The carrying unit can be inserted into the insertion slot from the front end of the insertion slot. The self-locking structure includes a cantilever and an interference portion. The cantilever is fixed to one end of the carrying unit. A protruding portion is formed at one side of the cantilever. A release portion is formed at the front end of the cantilever. The interference portion is formed on a side wall of the receiving cage. The interference portion recedes inward toward the rear of the insertion slot and has a locking slot behind the insertion slot. The interference portion and the cantilever form a self-locking structure. The protruding portion extends into the locking slot to create structural interference. One edge of the locking slot has a guiding portion, a neck portion and a locking portion. The guiding portion guides the movement of the protruding portion, such that the protruding portion moves along the guiding portion into a retaining slot defined by the neck portion and the locking portion.

In summary of the above, the self-locking structure of the present disclosure creates structural interference between the locking slot and the cantilever to achieve the effects of self-locking and protection against overload. Through the design of the abovementioned structure, the carrying device and the self-locking structure thereof of the present disclosure is more easily assembled, disassembled, and durable.

In order to further the understanding regarding the present disclosure, the following embodiments are provided along with illustrations to facilitate the disclosure of the present disclosure.

### BRIEF DESCRIPTION OF THE DRAWINGS

FIG. 1 shows a schematic diagram of a carrying device according to a first embodiment of the present disclosure;

FIG. 2 shows a schematic diagram of a carrying unit 120 inserted into a receiving cage 110 according to the first embodiment of the present disclosure;

FIG. 3A shows a schematic diagram of an assembled carrying device according to the first embodiment of the present disclosure;

FIG. 3B is an enlarged view of a portion of FIG. 3A;

FIG. 4A shows a partial side view of an assembled carrying device according to the first embodiment of the present disclosure;

FIG. 4B shows a partial top view of an assembled carrying device according to the first embodiment of the present disclosure;

FIG. 4C shows a partial view of a carrying device during assembly according to the first embodiment of the present disclosure;

FIG. 4D shows a schematic diagram of a cantilever and an interference portion interfering with each other according to the first embodiment of the present disclosure;

FIG. 4E shows a schematic diagram of a cantilever locked to an interference portion according to the first embodiment of the present disclosure;

FIG. 5 shows a schematic diagram of an interference portion according to a second embodiment of the present disclosure;

FIG. 6 shows a schematic diagram of an interference portion according to a third embodiment of the present disclosure; and

FIG. 7 shows a schematic diagram of an interference portion according to a fourth embodiment of the present disclosure;

### DETAILED DESCRIPTION OF THE PREFERRED EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

### First Embodiment

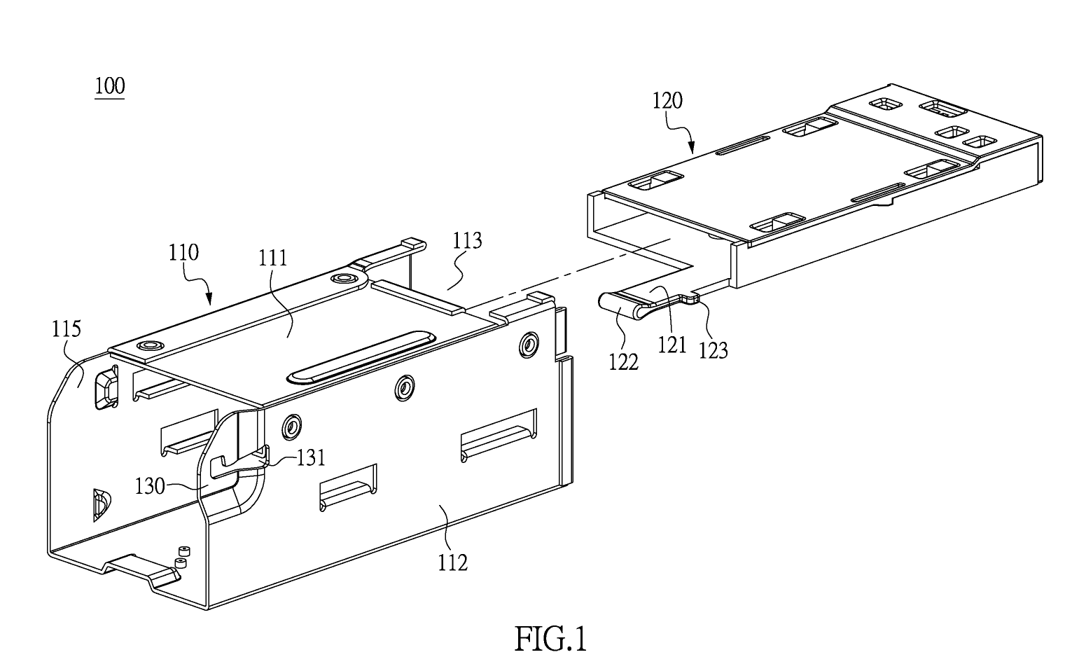

FIG. 1 shows a schematic diagram of a carrying device according to a first embodiment of the present disclosure. The carrying device 100 includes a receiving cage 110 and a carrying unit 120. The receiving cage 110 has an upper cover 111 and a casing 115. The casing 115 and the upper cover 111 define an insertion slot 113. The carrying unit 120 can be inserted from the front of the insertion slot 113 along an insertion direction into the insertion slot 113. A side wall 112 of the casing 115 has an interference portion 130 which recedes inward toward the rear of the insertion slot 113. The bending portion of the interference portion 130 has a locking slot 131 arranged behind the insertion slot 113. A cantilever 121 is disposed at one end of the carrying unit 120. A protruding portion 123 is formed at one side of the cantilever 121. A release portion 122 is formed at the front end of the cantilever 121. When the carrying unit 120 is inserted, the protruding portion 123 extends into the locking slot 131 to create structural interference therewith.

The cantilever 121 is disposed at the rear end of the carrying unit 120. The front end of the carrying unit 120 can accommodate control panels and other electronic devices. The cantilever 121 extends backward from the rear end of the carrying unit 120. The width of the carrying unit 120 falls within the two sides of the carrying unit 120. The locking slot 131 is generally slot-shaped and arranged to the side of the cantilever 121 in order to structurally interfere with the protruding portion 123. The shape of the locking slot 131 affects the movement path of the protruding portion 123 and deforms the cantilever 121 to create an elastic force. After the protruding portion 123 passes the neck portion of the locking slot 131, the elastic force in the cantilever 121 drives the protruding portion 123 into the retaining structure of the locking slot 121, thereby achieving the function of self-locking.

The receiving cage 110 can be disposed in the server (not shown in the figures). The carrying unit 120 is for carrying an electronic device such as a control panel, a human-computer interface device (not shown in the figures), etc. The receiving cage 110 of FIG. 1 is only one embodiment of many of the present disclosure. The casing structure of the receiving cage 110 can be modified according to need. Likewise, the structure of the carrying unit 120 can also be modified according to the components to be carried. FIG. 1 illustrates only one embodiment of the many possible. A person skilled in the art can derive other embodiments according to the present embodiment, details of which are not further described.

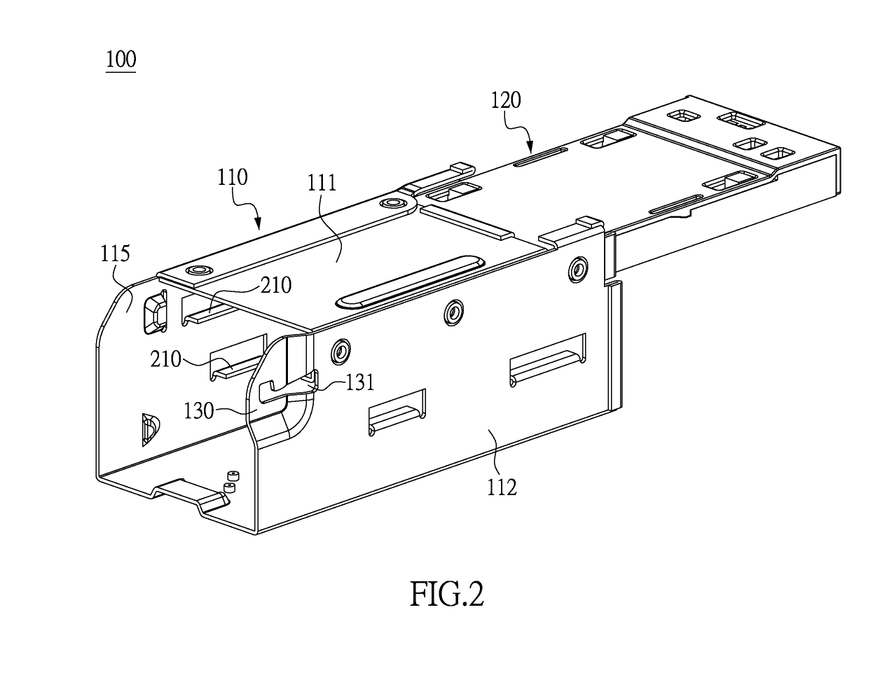

FIG. 2 shows a schematic diagram of a carrying unit 120 inserted into a receiving cage 110 according to the first embodiment of the present disclosure. Sliding rails 210 are disposed inside the receiving cage 110 for limiting the sliding direction of the carrying unit 120. The structure of the sliding rails 210 can be modified according to needs and is not limited to that of FIG. 2. The carrying unit 120 can be inserted into the insertion slot 113 of the receiving cage 110 along the insertion direction. During assembly of the receiving cage 110 and the carrying unit 120, the cantilever 121 of the carrying unit 120 slides into the insertion slot 113 and toward the interference portion 130.

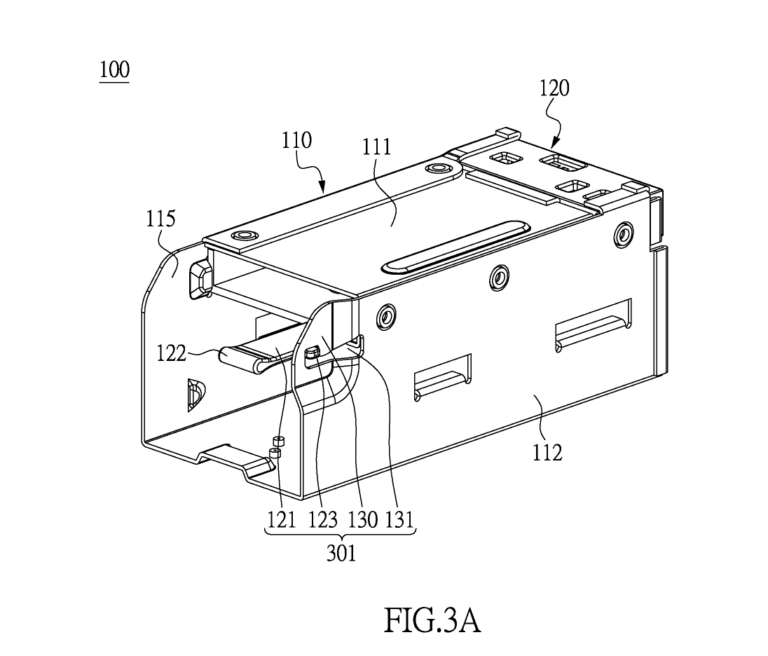

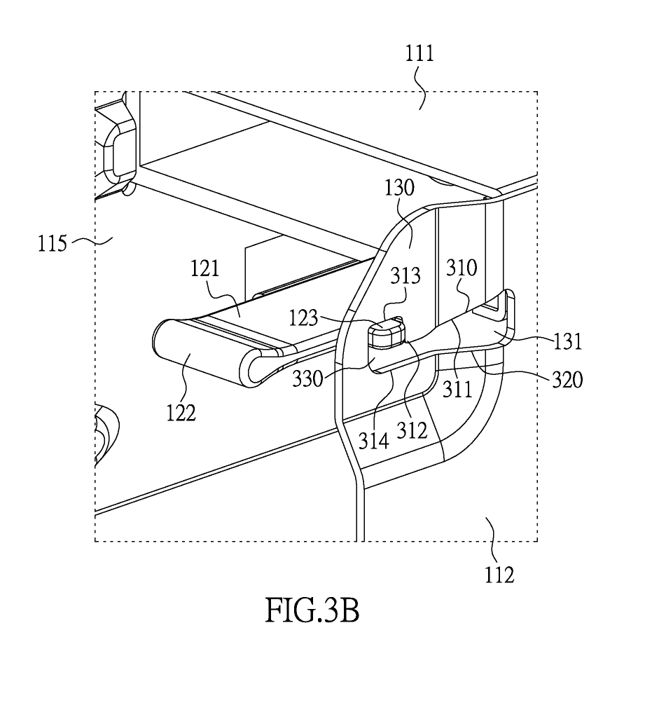

FIG. 3A shows a schematic diagram of an assembled carrying device according to the first embodiment of the present disclosure. FIG. 3B is an enlarged view of a portion of FIG. 3A. The interference portion 130 and the cantilever 121 form a self-locking structure 301. When the carrying unit 120 slides to the end of the insertion slot 113, the protruding portion 123 is pushed into the retaining slot 330 to achieve the function of self-locking. The interference portion 130 and the cantilever 121 interfere with each other when the carrying unit 120 is inserted into the receiving cage 110. Deformation and elastic force is created in the cantilever 121 due to interference from the interference portion 130. Upon arriving the locking position, the elastic force in the cantilever 121 provides a restoring force to achieve the effect of self-locking.

The following describes the structure of the self-locking structure 301 in detail. Referring to FIG. 3B, the upper edge 310 of the locking slot 131 has structural variation. Along the direction of insertion, the upper edge 310 is formed sequentially with a guiding portion 311, a neck portion 312 and a locking portion 313. The neck portion 312 is positioned between the guiding portion 311 and the locking portion 313. The neck portion 312 and the locking portion 313 define the retaining slot 330 for accommodating the protruding portion 123 at the locking position. In the present embodiment, the guiding portion 311 is a slanted edge facing the back of the insertion slot 113 and arranged at the same side as the protruding portion 123. The slanted edge can be slant from above the cantilever 121 to below the cantilever or sideways to drive the protruding portion 123 to slide along the slanted edge. When inserting the carrying unit 120, the guiding portion 311 is able to guide the movement of the protruding portion 123 such that the protruding portion 123 moves along the guiding portion 311 into the retaining slot 330 defined by the locking portion 313 and the neck portion 312. The carrying unit 120 is thereby fixed. The neck portion 312 is in front of the guiding portion 311 and blocks the protruding portion 123 from being drawn backward.

A blocking portion 314 is formed at the lower edge 320 of the locking slot 131. The position of the blocking portion 314 is in front of the retaining slot 330 for limiting the movement space of the protruding portion 123. The blocking portion 314 protects against overload. When the user presses the release portion 122 at the front of the cantilever 121 downward to unlock the carrying unit 120, the downward motion of the protruding portion 123 is limited by the blocking portion 314, thereby protecting the cantilever 121 from being damaged from excessive downward bending.

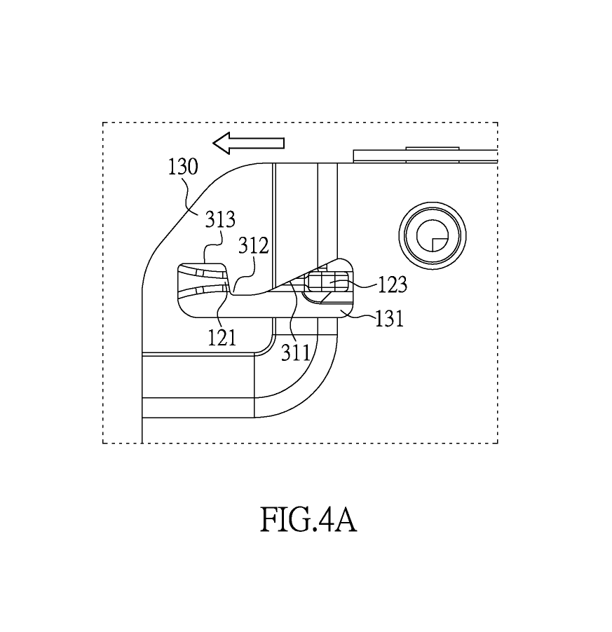

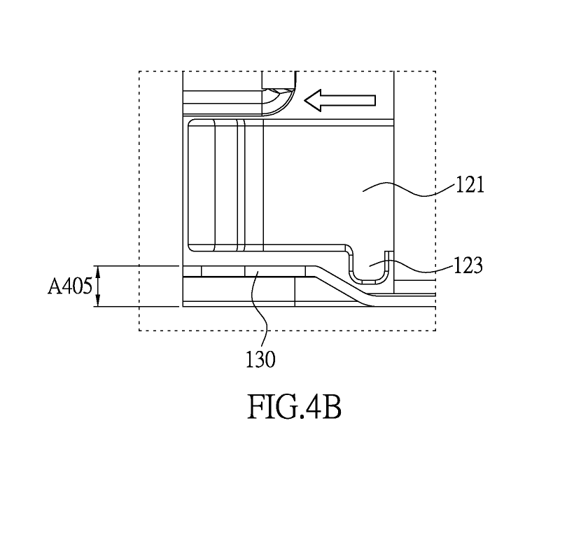

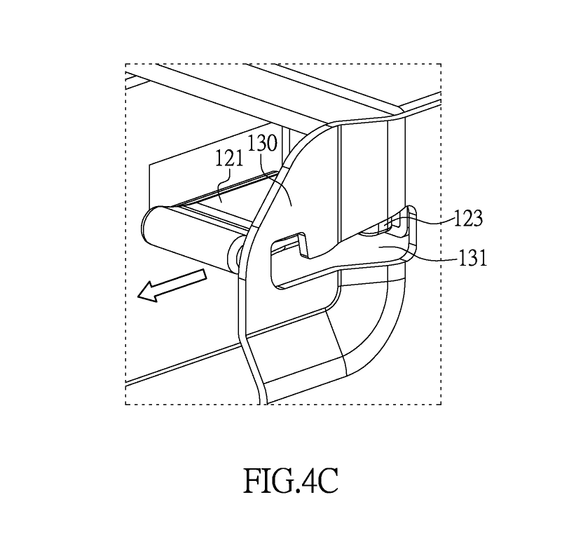

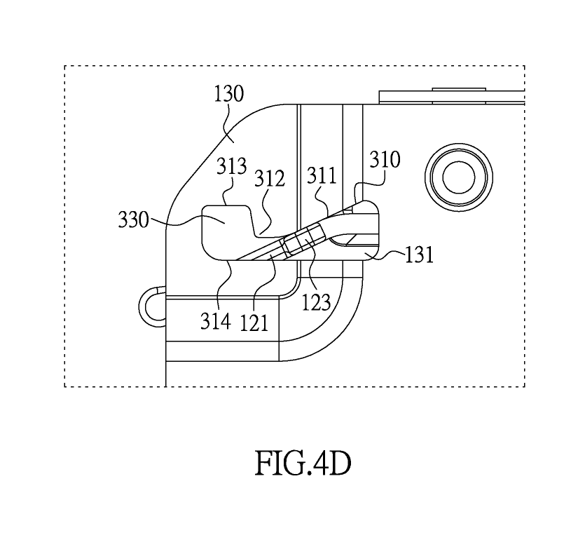

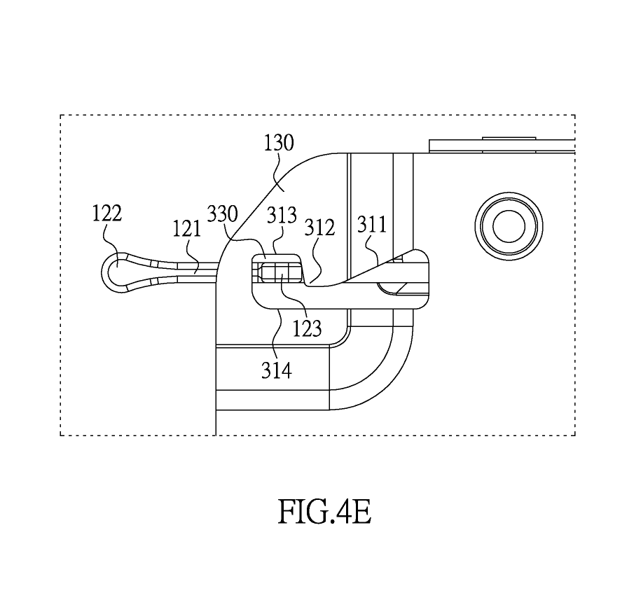

The following describes the self-locking method of the self-locking structure 301. FIG. 4A shows a partial side view of an assembled carrying device according to the first embodiment of the present disclosure. FIG. 4B shows a partial top view of an assembled carrying device according to the first embodiment of the present disclosure. FIG. 4C shows a partial view of a carrying device during assembly according to the first embodiment of the present disclosure. When the carrying unit 120 is inserted into the receiving cage 110, the protruding portion 123 on one side of the cantilever 121 approaches the locking slot 131 of the interference portion 130 as shown in FIG. 4A, FIG. 4B and FIG. 4C, wherein the arrow indicate the direction of insertion. An interference region A405 is defined by the receding space of the interference portion 130 behind the insertion slot 113. The locking slot 131 is positioned at the bending portion of the interference portion 130, and falls in the interference region A405. The protruding portion 123 extends toward the side wall 112 into the interference region A405 to structurally interfere with the locking slot 131. In the process of insertion, the protruding portion 123 is inserted into the locking slot 131 along the direction of insertion and structurally interferes with the guiding portion 311 on the upper edge 310 of the locking slot 131.

FIG. 4D shows a schematic diagram of a cantilever and an interference portion interfering with each other according to the first embodiment of the present disclosure. FIG. 4E shows a schematic diagram of a cantilever locked to an interference portion according to the first embodiment of the present disclosure. The cantilever 121 is an elastic cantilever made of materials such as plastic or metal. When interfered, the cantilever 121 bends and creates an elastic force. When the protruding portion 123 contacts the guiding portion 311, the guiding portion 311 guides the movement of the protruding portion 123 such that the cantilever 121 bends downward to create an elastic force toward the guiding portion 311 (slanted edge), as shown in FIG. 4D. The elastic force created in the cantilever 121 provides a restoring force for self-locking such that when the protruding portion 123 passes the neck portion 312, the protruding portion 123 is restored upward into the retaining slot 330, thereby achieving the effect of self-locking as shown in FIG. 4E.

The movement of the protruding portion 123 is limited to the region formed by the neck portion 312, the locking portion 313 and the blocking portion 314. At this moment the carrying unit 120 is automatically fixed in the insertion slot 113. When the user intends to retrieve the carrying unit 120, the release portion 122 at the front of the cantilever 121 can be pressed downward to disengage the protruding portion 123 from the interference portion 130 (neck portion 312), and pull out the carrying unit 120. The blocking portion 314 protects against overload at this moment, so as to prevent the user from over pressing and damaging the cantilever 121.

In the present embodiment, the upper edge 310 of the locking slot 131 has structural variations such that the sliding path of the protruding portion 123 is not a straight line. The sliding path causes the cantilever 121 to deform and create an elastic force. When reaching the locking position, the cantilever 121 restores its shape to achieve the function of self-locking. The lower edge 320 of the locking slot 131 acts as the blocking portion 314 for limiting the extent of deformation of the cantilever 121. The locking slot 131 can be embodied by many forms, e.g. an opening, a gap, a groove, or a track protruding on the inner side of the side wall 112. The locking slot 131 can be indented on the inner side of the side wall 112 or pass through the entire thickness of the side wall 112. The present disclosure is not limited thereto. A person skilled in the art can derive other embodiments from the embodiments described above, which are not further detailed herein.

The elastic cantilever 121 can provide force for self-locking. The release portion 122 of the cantilever 121 is curved to facilitate exertion of force by fingers and is simple to use. The main body of the cantilever 121 and the release portion 122 are positioned outside the interference region A405 to avoid affecting the insertion of the carrying unit 120. The protruding portion 123 does not protrude beyond the two sides of the carrying unit 120 so as to not affect the insertion of the carrying unit 120. However, the interference portion 130 must recedes inward in order to structurally interfere with the protruding portion 123. The release portion 122 is formed by the front end of the cantilever 121 and is a single piece with the main body of the cantilever 121. No assembly is required, so the release portion 122 is easy to operate, has a low cost and is not easily damaged.

It is worth noting that the casing 115 can be formed by a multiple units, e.g. an assembly of an upper casing and a lower casing to form the interference portion 130 and the locking slot 131. A person skilled in the art can easily deduce other embodiments of the casing 115 and the interference portion 130 mentioned in the above embodiment, which are not further detailed herein.

### Second Embodiment

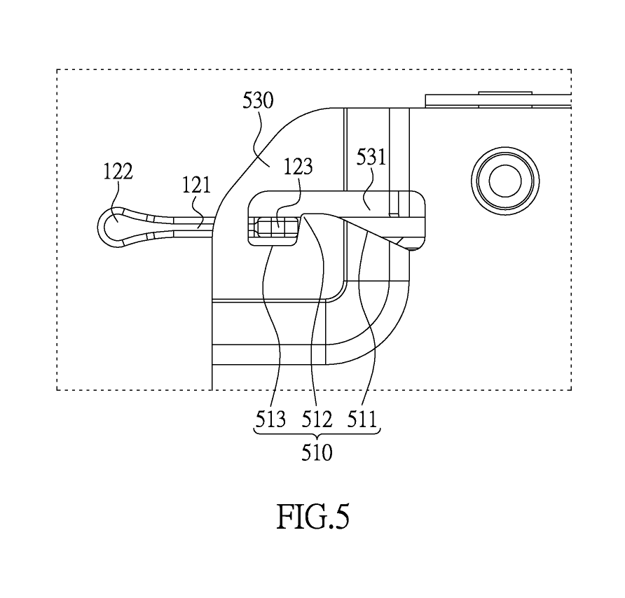

The interference portion 130 of the first embodiment can have many embodiments. FIG. 5 shows a schematic diagram of an interference portion according to a second embodiment of the present disclosure. The difference between FIG. 5 and the first embodiment lies mainly in the shape of the locking slot 531 is an inverted image of the shape of the locking slot 131. The interference portion 530 is likewise formed on the side wall 112 of the receiving cage 110 bending inward. The locking slot 531 is positioned at the portion of bending. Along the direction of insertion, the lower edge 510 of the locking slot 531 is formed sequentially with a guiding portion 511, a neck portion 512 and a locking portion 513. The guiding portion 511, the neck portion 512 and the locking portion 513 are similar to their respective counterparts in FIG. 3B, except that their orientations are reversed.

When the carrying unit 120 is inserted, the cantilever 121 is bent upward by the guiding portion 511 and creates a downward elastic force. Then, when the protruding portion 123 passes the neck portion 512, due to the elastic force of the cantilever 121, the protruding portion 123 moves downward into the groove defined by the neck portion 512 and the locking portion 513, thereby achieving the function of self-locking. During unlocking, the user can pull the release portion 122 of the cantilever 121 upward to disengage the cantilever 121 from the interference portion 530.

The structural movement of the second embodiment is similar to that of the first embodiment. The main difference lies in the structural difference of the interference portion 530. The interference portion 530 and the cantilever 121 likewise form a self-locking structure.

A person skilled in the art can easily deduce other embodiments of the interference portion 530 and the cantilever 121 mentioned in the above embodiment, which are not further detailed herein.

### Third Embodiment

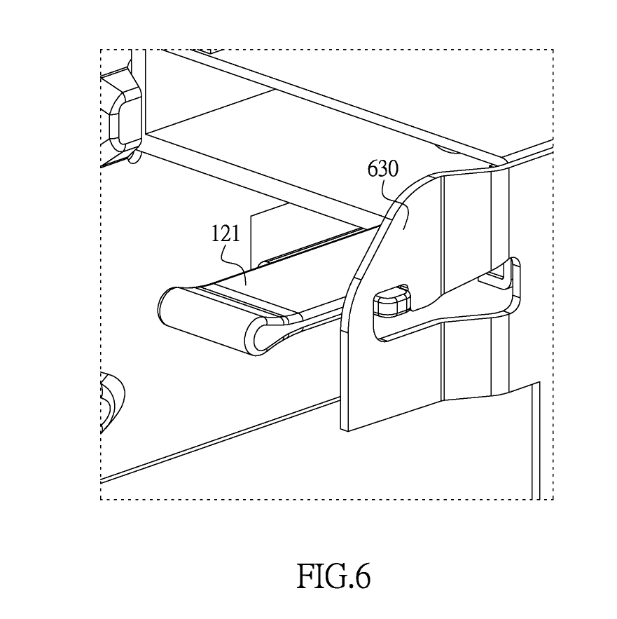

The interference portion 130 of the first embodiment can have many embodiments. FIG. 6 shows a schematic diagram of an interference portion according to a third embodiment of the present disclosure. The main difference between FIG. 6 and the first embodiment lies in the interference portion 630. The interference portion 130 is a receding structure, whereas the interference portion 630 does not have a bottom portion and is a bent structure. The interference portion 630 can be produced by stamping which is simpler and cost less. The structural movement of the embodiment in FIG. 6 is similar to the first embodiment and is not further detailed herein.

### Fourth Embodiment

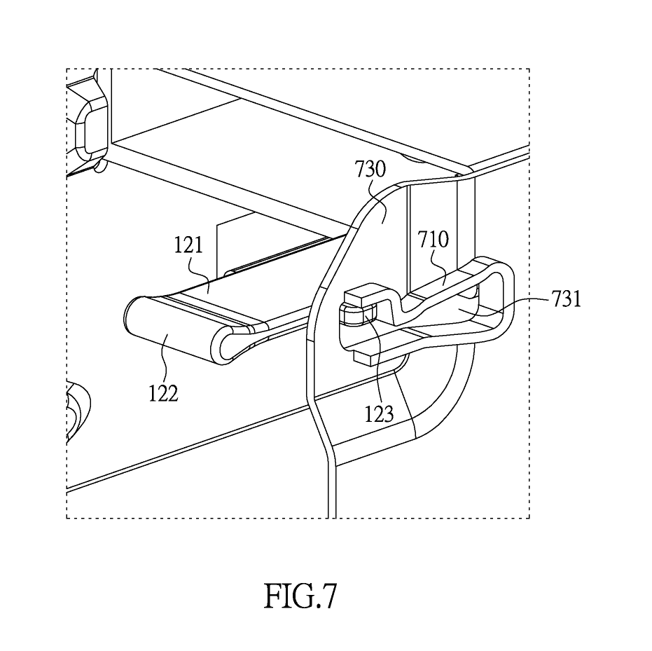

The interference portion 130 of the first embodiment can have many embodiments. FIG. 7 shows a schematic diagram of an interference portion according to a fourth embodiment of the present disclosure. The main difference between FIG. 7 and the first embodiment lies in that the edge of the locking slot 731 of the interference portion 730 has a protruding rail 710 serving as a sliding rail for the protruding portion 123, thereby making the sliding of the protruding portion 123 smoother. The structural movement of the embodiment in FIG. 7 is similar to the first embodiment and is not further detailed herein. A person skilled in the art can deduce other embodiments of the interference of the present embodiment, which are not further detailed herein.

The abovementioned carrying device and the self-locking structure thereof can be applied in servers to carry control panels and other human-computer interface devices, or applied in casings for carrying electronic devices. The self-locking structure and the unlocking component (release portion) are arranged in the structure to prevent the user from accidentally releasing the human-computer interface devices. Additionally, the structure of the self-locking structure consists of only two components (cantilever and interference portion), instead of multiple components, so the production cost and the durability are ideal and can be mass produced.

In summary of the above, the carrying device and the self-locking structure thereof can achieve the functions of self-locking and protection against overload. Moreover, the structure of the carrying device is simple, is not easily damaged, has a low production cost, and is very suitable for being adapted to servers for carrying electronic devices.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. A carrying device adapted to a server for carrying an electronic device, comprising:
a carrying unit for carrying the electronic device, wherein one end of the carrying unit has a cantilever, one side of the cantilever has a protruding portion, and the front end of the cantilever has a release portion; and
a receiving cage mounted in the server, wherein the receiving cage has an insertion slot for inserting the carrying unit from the front of the insertion slot, a side wall of the receiving cage has an interference portion receding inward behind the insertion slot and having a locking slot positioned behind the insertion slot;
wherein the interference portion and the cantilever form a self-locking structure, the protruding portion extends into the locking slot for structurally interference with the locking slot, an edge of the locking slot has a guiding portion, a neck portion and a locking portion, the guiding portion guides the movement of the protruding portion, the protruding portion moves along the guiding portion into a retaining slot defined by the neck portion and the locking portion.

2. The carrying device according to claim 1, wherein the guiding portion is a slanted edge for interfering with the protruding portion and guiding the protruding portion to deform the cantilever and create an elastic force in the cantilever.

3. The carrying device according to claim 1, wherein the interference portion further has a blocking portion opposite the locking portion, and the position of the blocking portion is in front of the retaining slot for limiting the movement space of the protruding portion.

4. The carrying device according to claim 1, wherein the edge of the locking slot is an upper edge or a lower edge of the locking slot.

5. The carrying device according to claim 1, wherein the edge of the locking slot has a protruding rail for the protruding portion to slide upon.

6. The carrying device according to claim 1, wherein the receiving cage has a casing and an upper cover disposed on the casing, and the upper cover and the casing define the insertion slot.

7. The carrying device according to claim 1, wherein the release portion is positioned outside the locking slot.

8. A self-locking structure of a carrying device, wherein the carrying device has a carrying unit and a receiving cage, the receiving cage is disposed in a server, the carrying unit carries an electronic device receiving cage has an insertion slot for inserting the carrying unit from the front of the insertion slot, and the self-locking structure comprises:
a cantilever, fixed at one end of the carrying unit, and having a protruding portion at one side of the cantilever and a release portion at the front end of the cantilever; and
an interference portion formed at a side wall of the receiving cage, receding inward behind the insertion slot and having a locking slot behind the insertion slot;
wherein the interference portion and the cantilever form a self-locking structure, the protruding portion extends into the locking slot for structurally interference with the locking slot, an edge of the locking slot has a guiding portion, a neck portion and a locking portion, the guiding portion guides the movement of the protruding portion, the protruding portion moves along the guiding portion into a retaining slot defined by the neck portion and the locking portion.

9. The self-locking structure according to claim 8, wherein the guiding portion is a slanted edge for interfering with the protruding portion and guiding the protruding portion to deform the cantilever and create an elastic force in the cantilever.

10. The self-locking structure according to claim 8, wherein the interference portion further has a blocking portion opposite the locking portion, and the position of the blocking portion is in front of the retaining slot for limiting the movement space of the protruding portion.

11. The self-locking structure according to claim 8, wherein the edge of the locking slot is an upper edge or a lower edge of the locking slot.

12. The self-locking structure according to claim 8, wherein the edge of the locking slot has a protruding rail for the protruding portion to slide upon.

13. The self-locking structure according to claim 8, wherein the receiving cage has a casing and an upper cover disposed on the casing, and the upper cover and the casing define the insertion slot.

14. The self-locking structure according to claim 8, wherein the release portion is positioned outside the locking slot.
